(19) United States
(12) Patent Application Publication
(10) Pub. No.: US 2023/0221188 A1
(43) Pub. Date: Jul. 13, 2023

(54) HIGH TEMPERATURE SENSOR AND SYSTEM

(71) Applicants: Navin Sakthivel, Spring, TX (US); Aaron Avagliano, Tomball, TX (US)

(72) Inventors: Navin Sakthivel, Spring, TX (US); Aaron Avagliano, Tomball, TX (US)

(73) Assignee: Baker Hughes Oilfield Operations LLC, Houston, TX (US)

(21) Appl. No.: 17/570,525

(22) Filed: Jan. 7, 2022

(51) Int. Cl. G01K 7/04; H01L 35/32; G01K 1/16; G01K 13/00

(52) U.S. Cl. CPC G01K 7/04; H01L 35/32; G01K 1/16; G01K 13/00; G01K 2215/00

(57) ABSTRACT

A sensor having thermal stability at greater than 900° C., including a sensor body comprising an energy harvesting thermal electric generator, a heat sink in thermally conductive contact with the body, and a conductor electrically attached to the body, the conductor surrounded by a ceramic dielectric material. A borehole system including a borehole in a subsurface formation, a sensor disposed in the borehole.

### BACKGROUND

In many industries, including the resource recovery and fluid sequestration industries, sensors are both important to operations and subject to extreme thermal stress that rapidly degrades accuracy. Such conditions causes poor reliability and excessive maintenance. Greater reliability for sensors used in high temperature applications would be well received in industry.

### SUMMARY

An embodiment of a sensor having thermal stability at greater than 900° C., including a sensor body comprising an energy harvesting thermal electric generator, a heat sink in thermally conductive contact with the body, and a conductor electrically attached to the body, the conductor surrounded by a ceramic dielectric material.

An embodiment of a borehole system including a borehole in a subsurface formation, a sensor disposed in the borehole.

### BRIEF DESCRIPTION OF THE DRAWINGS

The following descriptions should not be considered limiting in any way. With reference to the accompanying drawings, like elements are numbered alike:

FIG. 1 is a schematic cross section of a tubular member with a sensor as disclosed herein;

FIG. 2 is an enlarged schematic view of the sensor body illustrated in FIG. 1;

FIG. 3 is an enlarged schematic view of the power and signal component illustrated in FIG. 1; and

FIG. 4 is a view of a borehole system including the sensor disclosed herein.

### DETAILED DESCRIPTION

A detailed description of one or more embodiments of the disclosed apparatus and method are presented herein by way of exemplification and not limitation with reference to the Figures.

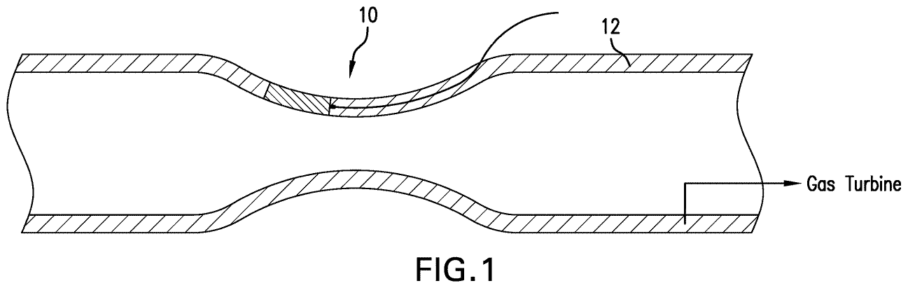

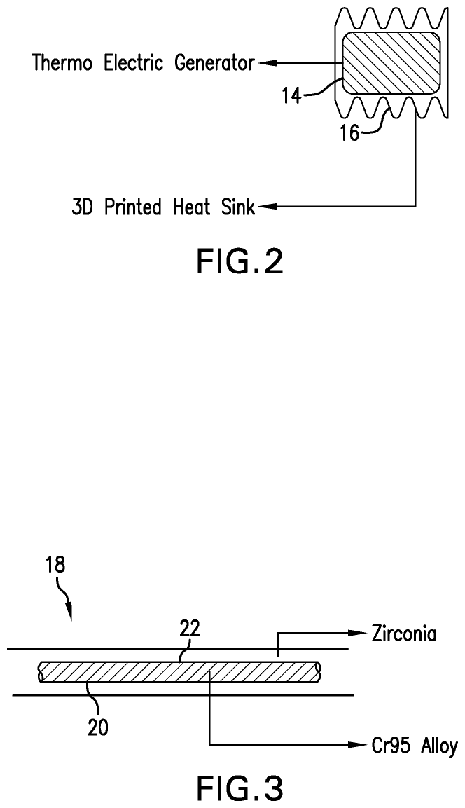

Referring to FIGS. 1-3, a sensor 10 for temperature applications above 900° C. is illustrated in a tubular member 12. The sensor 10 includes a thermoelectric generator (TEG) 14, such as a Silicone-Germanium alloy-based TEG, disposed within a heat sink 16 and a power and signal conductor 18 in electrical communication with the TEG 14.

More specifically, TEG 14 is of the type that is commercially available and commonly employed for generation of power. For the present purposes, however, the TEG is used as a sensor for temperature by querying periodically or continuously monitoring an energy output of the TEG 14 and correlating that energy output to temperature in the vicinity of the TEG. Because the temperature range contemplated for the sensor disclosed herein is extremely high, greater than 900° C., there are impediments to using a TEG for a sensor. There is a nonlinearity and a transient nature of TEGs at room temperature that would appear to make a TEG a poor choice for a temperature sensor at temperatures greater than 900° C. As the temperature increases, electrical conductivity and thermal conductivity increases (if a semiconductor) or decreases if a metal. However, the efficiency or figure of merit of a TEG is directly proportional to electrical conductivity and temperature while inversely proportional to thermal conductivity. This results in a disproportionality in the energy generated over a broad range of temperature and particularly at high temperatures such as greater than 900° C. The effect creates a nonlinearity in the energy output across a higher temperature range. In other words, the energy output from the TEG becomes less predictable at high temperature and hence the TEG does not appear to be a consistent bellwether for temperature as the correlation between energy production and temperature is not linear. In addition to temperature, time at temperature is also an issue for TEGs. As time increases, the amount of heat energy absorbed by the system increases up to the thermal heat capacity of the material. The quantity of heat absorbed by the system at a given temperature as a function of time will affect the thermal conductivity and electrical conductivity because it provides kinetic energy for the free electrons in the material. Hence, TEGs are also transient in nature, meaning that the energy output will vary even at a consistent temperature held over time. Rather, as the TEG becomes isothermal with the surrounding environment, energy production stops. Again, correlating energy output to actual environmental temperature might be considered elusive. As configured according to this disclosure, however, both the nonlinearity and transient problems are solved by thermally coupling the TEG 14 with the heat sink 16. The heat sink in some embodiments is an alumina material. In some embodiments, the heat sink 16 is additively manufactured with the TEG which provides for maximum heat transfer efficiency. And in yet some embodiments, the alumina is formed with a fin-like geometry. The heat sink 16 reduces nonlinearity and transience by conducting heat away from the TEG 14 and thereby preserving available heat capacity of the material of the TEG, which ensures a greater thermal difference between the fluid to be measured and the TEG 14. So configured, the TEG 14 exhibits near zero drift and a low hysteresis (“near” meaning about 2% and “low” meaning about 10%). In addition, high temperature application of a TEG 14 for temperature measurement is hindered by power and signal issues. It is insufficient to employ commonly used conductors since they suffer from distinctly increased resistance at higher temperatures, those temperatures being substantially lower than the contemplated environments for the herein disclosed sensor. To solve this problem the inventors hereof have discovered that a high temperature conductor in a ceramic dielectric material provides sufficient power and signal conduction for reliable sensing at high temperatures such as greater than 900° C. In one embodiment, the power and signal conductor 18 comprises Chromium 95 alloy (e.g. 30%) as a conduction medium 20 disposed in a zirconia dielectric material sheath 22 or dispersed in the zirconia dielectric material. The specific embodiment mentioned benefits from a matched coefficient of thermal expansion (CTE). As used herein the term “matched” means that the conductor or dielectric material is within about 4% of the CTE of the other of the conductor or the dielectric material.

Additive manufacturing is appropriate for the conductor and ceramic dielectric material, for the heat sink (as noted above) and for the entire sensor 10.

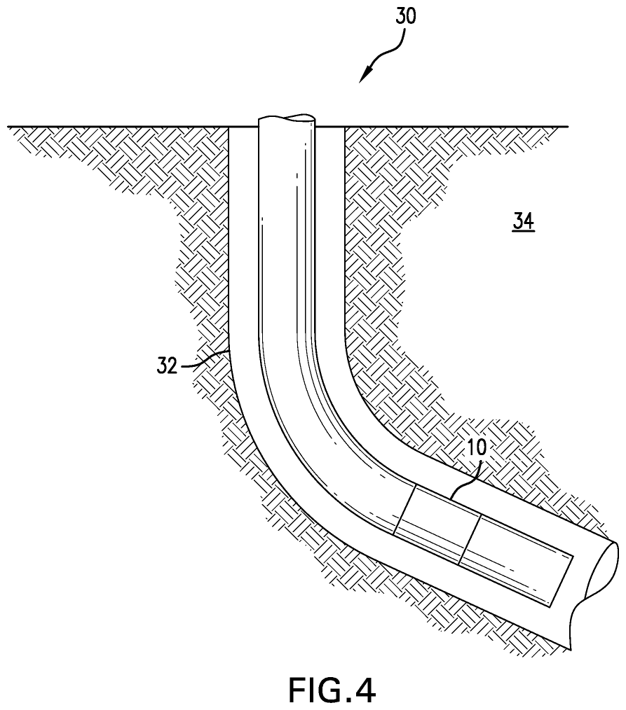

Referring to FIG. 4, a borehole system 30 is illustrated. The system 30 includes a borehole 32 in a subsurface formation 34. Within the borehole is a sensor 10 as disclosed herein.

Set forth below are some embodiments of the foregoing disclosure:

Embodiment 1: A sensor having thermal stability at greater than 900° C., including a sensor body comprising an energy harvesting thermal electric generator, a heat sink in thermally conductive contact with the body, and a conductor electrically attached to the body, the conductor surrounded by a ceramic dielectric material.

Embodiment 2: The sensor as in any prior embodiment having a thermal stability at greater than 1000° C.

Embodiment 3: The sensor as in any prior embodiment wherein the heat sink is alumina.

Embodiment 4: The sensor as in any prior embodiment wherein the heat sink is additively manufactured with the sensor body and includes fins.

Embodiment 5: The sensor as in any prior embodiment wherein the conductor comprises chromium 95 alloy.

Embodiment 6: The sensor as in any prior embodiment wherein ceramic dielectric material comprises zirconia.

Embodiment 7: The sensor as in any prior embodiment wherein the conductor and the ceramic dielectric material exhibit overlapping coefficients of thermal expansion.

Embodiment 8: The sensor as in any prior embodiment wherein the coefficients of thermal expansion of the conductor and the ceramic dielectric material are within 4% of an exact match.

Embodiment 9: The sensor as in any prior embodiment wherein the conductor and ceramic dielectric material are additively manufactured.

Embodiment 10: The sensor as in any prior embodiment wherein the entire sensor is additively manufactured.

Embodiment 11: A borehole system including a borehole in a subsurface formation, a sensor disposed in the borehole, the sensor as in any prior embodiment.

The use of the terms “a” and “an” and “the” and similar referents in the context of describing the invention (especially in the context of the following claims) are to be construed to cover both the singular and the plural, unless otherwise indicated herein or clearly contradicted by context. Further, it should be noted that the terms “first,” “second,” and the like herein do not denote any order, quantity, or importance, but rather are used to distinguish one element from another. The terms “about”, “substantially” and “generally” are intended to include the degree of error associated with measurement of the particular quantity based upon the equipment available at the time of filing the application. For example, “about” and/or “substantially” and/or “generally” can include a range of ±8% or 5%, or 2% of a given value.

The teachings of the present disclosure may be used in a variety of well operations. These operations may involve using one or more treatment agents to treat a formation, the fluids resident in a formation, a wellbore, and/or equipment in the wellbore, such as production tubing. The treatment agents may be in the form of liquids, gases, solids, semi-solids, and mixtures thereof. Illustrative treatment agents include, but are not limited to, fracturing fluids, acids, steam, water, brine, anti-corrosion agents, cement, permeability modifiers, drilling muds, emulsifiers, demulsifiers, tracers, flow improvers etc. Illustrative well operations include, but are not limited to, hydraulic fracturing, stimulation, tracer injection, cleaning, acidizing, steam injection, water flooding, cementing, etc.

While the invention has been described with reference to an exemplary embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof Therefore, it is intended that the invention not be limited to the particular embodiment disclosed as the best mode contemplated for carrying out this invention, but that the invention will include all embodiments falling within the scope of the claims. Also, in the drawings and the description, there have been disclosed exemplary embodiments of the invention and, although specific terms may have been employed, they are unless otherwise stated used in a generic and descriptive sense only and not for purposes of limitation, the scope of the invention therefore not being so limited.

What is claimed is:

1. A sensor having thermal stability at greater than 900° C., comprising:
a sensor body comprising an energy harvesting thermal electric generator;
a heat sink in thermally conductive contact with the body; and
a conductor electrically attached to the body, the conductor surrounded by a ceramic dielectric material.

2. The sensor as claimed in claim 1 having a thermal stability at greater than 1000° C.

3. The sensor as claimed in claim 1 wherein the heat sink is alumina.

4. The sensor as claimed in claim 1 wherein the heat sink is additively manufactured with the sensor body and includes fins.

5. The sensor as claimed in claim 1 wherein the conductor comprises chromium 95 alloy.

6. The sensor as claimed in claim 1 wherein ceramic dielectric material comprises zirconia.

7. The sensor as claimed in claim 1 wherein the conductor and the ceramic dielectric material exhibit overlapping coefficients of thermal expansion.

8. The sensor as claimed in claim 7 wherein the coefficients of thermal expansion of the conductor and the ceramic dielectric material are within 4% of an exact match.

9. The sensor as claimed in claim 1 wherein the conductor and ceramic dielectric material are additively manufactured.

10. The sensor as claimed in claim 1 wherein the entire sensor is additively manufactured.

11. A borehole system comprising:
a borehole in a subsurface formation;
a sensor disposed in the borehole, the sensor as claimed in claim 1.
